(19) United States
(12) Patent Application Publication
(10) Pub. No.: US 2008/0283114 A1
(43) Pub. Date: Nov. 20, 2008

(54) Notebook carry case employing a solar energy charging and cooling system

(76) Inventor: Randolph Gray, Round Rock, TX (US)

Correspondence Address: Kevin R. Imes, 7309 Tanaqua Lane, Austin, TX, 78739, US

(21) Appl. No.: 11/983,316

(22) Filed: Nov. 8, 2007

Related U.S. Application Data
(60) Provisional application No. 60/857,577, filed on Nov. 8, 2006.

(51) Int. Cl. H01L 31/045

(52) U.S. Cl. 136/245

(57) ABSTRACT

A notebook carry case employing a solar energy charging and cooling system is disclosed. In one form, a solar energy charge and cooling system can include a first fan coupled to an interior lid portion of a housing configured to store a portable electronic device, and a solar panel array coupled to an exterior portion of the lid and operable to convert solar energy to power the first fan. The first fan can be responsive to the converted solar energy to reduce an operating temperature within the housing.

### CROSS REFERENCE RELATED TO APPLICATION

This application claims priority to United States Provisional Patent Application entitled “Notebook Carry Case Employing a Solar Energy Charging and Cooling System” having application Ser. No. 60/857,577 and filed on Nov. 8, 2006 and herein incorporated by reference.

### FIELD OF THE DISCLOSURE

The present disclosure generally relates to solar energy and, more particularly, to a notebook carry case employing a solar energy charging and cooling system.

### BACKGROUND

Power utilization of conventional hand-held electronic devices vary significantly depending on the application and utilization of a device. Some electronic devices include reduced power states that draw very little power when the electronic device is not in use. For example, a handheld computing device may use significantly more energy to process user inputs and display information within user interfaces such as thin film transistor active matrix displays (TFT displays). When the handheld computing device is not being used, it is placed in an off mode, sleep mode or other reduced power state to decrease or reduce power consumption.

Other electronic devices, such as some conventional cellular telephones, consume energy based on a user's interaction with a wireless network. For example, some conventional cellular telephones include off positions, standby modes for receiving phone calls or other incoming data services, and active mode for interacting with wireless networks to place and receive phone calls or requesting data services. Each mode of operation may have separate power demands or requirements.

Advancements in wireless networks may also increase power utilization of some electronic devices. For example, as cellular phones and handheld computing devices migrate to high speed wireless networks, power consumption of electronic devices may increase as a function of communicating and processing data via high-speed communication networks. This may result in more frequent charging of electronic devices.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 illustrates a carry case presented in a closed position according to one aspect of the disclosure;

FIG. 2 illustrates a carry case presented in an open position according to one aspect of the disclosure; and

FIG. 3 illustrates a solar energy charge and cooling system for a carry case according to one aspect of the disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application. The teachings can also be utilized in other applications and with several different types of architectures such as distributed computing architectures, client/server architectures, or middleware server architectures and associated components.

For purposes of this disclosure, a portable electronic device can include a notebook computer, portable computer system, a laptop computer, a PDA, a portable consumer electronic device, a wireless communicator or communication device, or any other suitable portable device and can vary in size, shape, performance, functionality, and price.

According to one aspect of the disclosure, a portable storage apparatus, such as a carry case and the like, can include a solar panel array coupled to an exterior portion of a lid of a housing, the solar panel array operable to convert solar energy to direct current (DC) power. The portable storage apparatus can also include a first temperature sensing device configured to sense an internal temperature of a cavity formed from the housing. The housing can also include a bottom portion. According to a further aspect, the portable storage apparatus can include a first fan coupled to an interior portion of the housing and responsive to the first temperature sensing device. In one form, the first temperature sensing device can be used to initiate activation of the first fan to reduce an operating temperature within the housing.

According to a further aspect of the disclosure, a solar energy charge and cooling system of a carry case is disclosed. The system includes a first fan coupled to an interior lid portion of a housing configured to store a portable electronic device, and a solar panel array coupled to an exterior portion of the lid and operable to convert solar energy to power the first fan. According to one aspect, the first fan can be responsive to the converted solar energy to reduce an operating temperature within the housing.

According to another aspect of the disclosure, a carry case is disclosed. The carry case can include a solar panel array coupled to an exterior portion of a lid of a housing. The solar panel array can be operable to convert solar energy to direct current (DC) power. The carry case can also include a first temperature sensing device configured to sense an internal temperature of a cavity formed within the housing. The housing also includes the lid and a bottom portion. The carry case can further include a fan controller responsive to the first temperature sensing device and operable to enable activation of the a first fan coupled a first fan coupled to an interior lid portion of a housing. The carry case can also include a second fan coupled to the bottom portion of the housing. In one form, the first fan is proximally located to the solar panel array to reduce an operating temperature of the solar panel array using energy converted by the solar panel array. Additionally, the second fan can be proximally located to a portable computer storage area of the bottom portion of the housing. The second fan can be responsive to the converted solar energy to reduce an operating temperature of the portable computer.

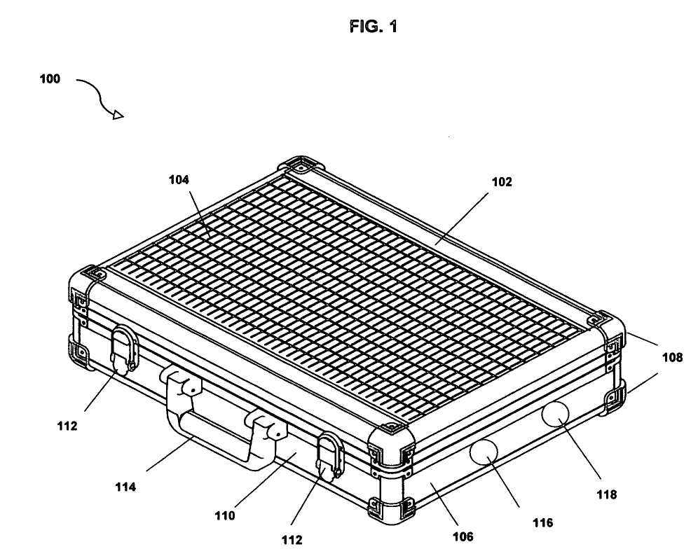

FIG. 1 illustrates a carry case, illustrated generally at 100, in a closed position according to one aspect of the disclosure. The carry case 100 can include a lid portion 102 incorporating a solar panel array 104 coupled to the lid portion 102 using a bonding agent, adhesive, rivet, screw and nuts, or various other coupling mechanism. In one form, the solar panel array 104 can include at least one thin-film solar panel operable to output approximately five (5) Watts of power. Thin-film solar panel technology is advantageously light-weight but at a performance cost. As such, the use of thin-film solar panels can reduce the overall weight of the carry case 100. In other forms, a solar panel array 104 can include a single or multi-crystalline cell solar panel to output converted solar power more efficiently, however an increase in the overall weight of the carry case 100 will be realized.

The carry case 100 also includes a bottom portion 106, and end portions 108 coupled along portions of the bottom portion 106 and the top portion 102. The end portions 108 can be formed from a hardened plastic, metal, rubber, or other type of material operable to protect the carry case during use. Additionally, the carry case 100 can be formed from as a hard case and can include durable aluminum laminated material, an aluminum formed shell, a polycarbonate shell, or various other types of materials to form the housing of the carry case 100. In one form, the carry case 100 can include a waterproof or water resistant housing.

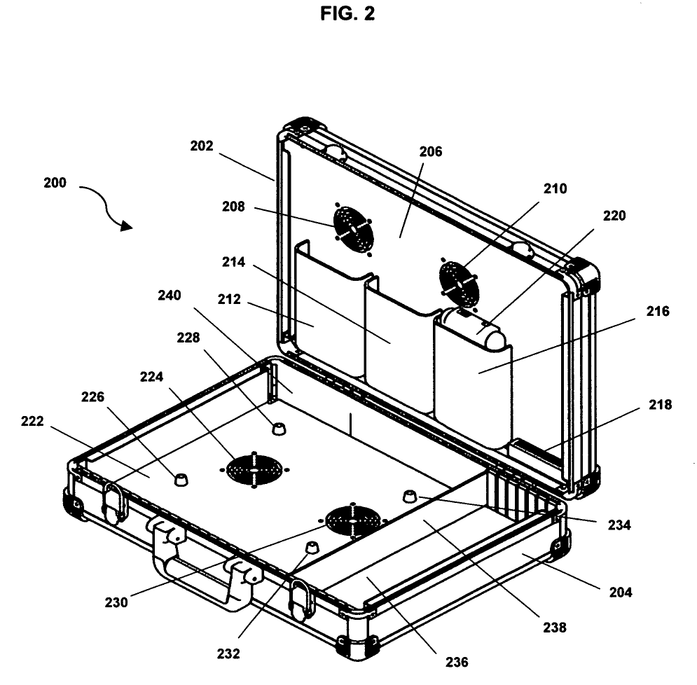

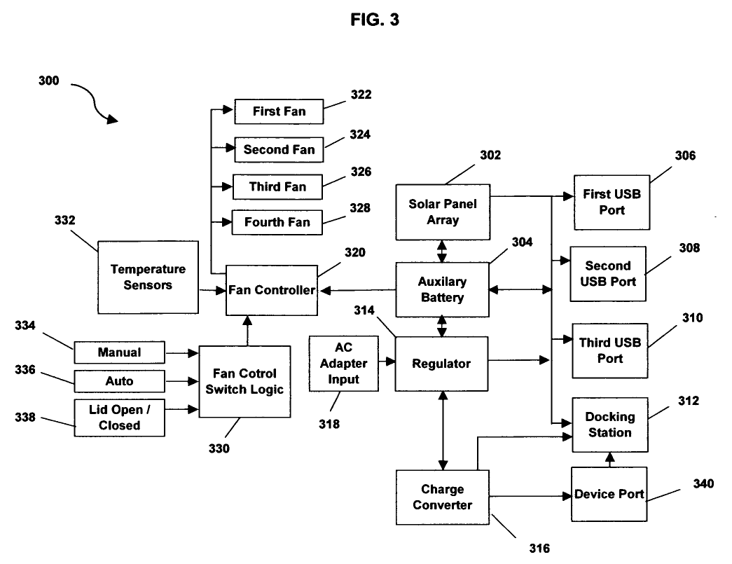

The carry case 100 can also include a front portion 110 including latches 112 to secure the top portion 102 and the bottom portion 106. A handle 114 can also be provided to support the carry case 100 during travel. The carry case 100 further includes a first air vent region 116 and a second air vent region 118 operably associated with a cooling system of the carry case 100 as described in FIG. 2 and FIG. 3 below. The carry case 100 can include additionally air vent regions as needed or desired. According to one aspect, the carry case 100 can also include wheels coupled to a portion of the carry case 100 as an overall size, weight, and materials of the carry case 100 can vary.

FIG. 2 illustrates a carry case 200, illustrated in an open position according to one aspect of the disclosure. The carry case 200 can include a lid portion 202 and a bottom portion 204. The lid portion 202 includes a first fan 208 and a second fan 210 mounted to an interior lid portion 206 of the carry case 200. The lid portion 202 also includes a first device cavity 212, a second device cavity 214 and a third device cavity 216. One or a combination of device cavities 212 and 214 can include a charge port to charge an electronic device (not illustrated) when mounted. The lid portion 202 can also include a third cavity 216 that includes an removable auxiliary battery 220 configured to store converted solar energy and output power as desired. The lid portion 202 can also include an array of USB ports 218 can be configured as a USB 2.0 ports that can be used to charge an electronic device coupled using a USB cable (not illustrated) coupled to one of the USB ports 218. In one form, the USB ports 218 can be configured as a USB hub that can be used to expand functionality of a laptop or other computing system operable to exploit use of USB enabled devices. For example, a laptop or notebook computer can be placed within the carry case 100 and a cable can be coupled from the laptop to the USB port 218 to enable access to the USB hub. In one form, the laptop can be used to power the USB port 218 operable as the USB hub. As such, a user can utilize the USB port 218 operable as a hub to couple one or more USB devices to the laptop. In this manner, a user need not remove a laptop from the carry case 100 to access USB ports of the laptop. Although illustrated as using a USB port and USB communication bus, other buses can also be employed as needed or desired.

The carry case 200 also includes the bottom portion 204 including an interior cavity 222 and a third fan 224 and a fourth fan 230 coupled using a third mount 232 and a fourth mount 234. The bottom portion 204 also includes a first offset 226, a second offset 228, a third offset 232, and a fourth offset 234 to offset a laptop when placed within the bottom portion 222. According to one aspect, the first fan 208 and the second fan 210 can be used to cool the solar panel and other devices mounted to the top portion 202. Additionally, the third fan 224 and the fourth fan 230 can be used to cool a laptop or notebook computer when placed within the bottom portion 222 of the carry case 200.

According to another aspect, the interior cavity 222 can include a divider 238 forming a second cavity 236. The second cavity 236 can be used to store various articles and in one form can be used to store a battery charger and AC charge adapter of a laptop (not illustrated). The divider 238 can also be configured as an adjustable divider to accommodate various notebook sizes.

According to another aspect, the carry case 200 can include a docking station 240 coupled to the bottom portion of the carry case 200. The docking station 240 can be used to couple a laptop to one or more resources of the carry case 200. For example, one or more of the USB ports 218, device ports 212, 214, 216, charge circuits, energy sources, power sources including AC adapter power sources, solar conversion power sources, battery sources, or other power sources, integrated resources such as wireless transceivers, satellite receives such as Sirrus or XM radio receivers, 802.11 or other short-range wireless transceivers such as Bluetooth and the like, one or more antennas operable to receive RF signals such as satellite radio, hi-definition radio, AM, FM, HDTV or other digital television signals, audio speakers that can include an amplifier, microphones, webcams, or any other resources that can be integrated as a part of the carry case 200 and accessed using the docking station 240. As such, resources can be integrated as a part of the carry case 200 or a user can couple one or a combination of resources to the device ports 212, 214, 216 allowing a user of a laptop to expand resources of the laptop while mounted within the carry case 200.

For example, a user can couple one or more USB devices to a laptop using the USB ports 218 to enable a user access to external resources such as memory sticks, communication modules, wireless pointers or mouse controllers, Bluetooth enabled devices, digital cameras, video cameras, digital music players, or various other USB devices that can be coupled to a USB port and accessed by a laptop placed within the carry case 200.

According to another aspect, the removable auxiliary battery 220 can also include one or more auxiliary batteries, such as lithium ion batteries that can be charged using solar energy or using an AC adapter and plug. The USB ports 218 can also be coupled to the removable auxiliary battery 220 to enable access to the stored auxiliary power, converted solar energy, or combinations thereof, to power an electronic device coupled to one of the USB ports 218. For example, the USB ports 218 may not be used as a USB bus, but may be used to only power a device that can be coupled to one of the USB ports 218. In one form, one or more of the device ports 212, 214, 216 can include a pocket configured to store items such as electronic devices, notepad, pens, or other accessories. In one form, one or a combination of device ports 212, 214, 216 can include charge ports to charge specific types of electronic devices such as iPods, cell phones, digital cameras, or various other types of electronic devices. In one form, the USB ports 218, or an additional number of USB ports, can be accessed while the lid of the carry case is closed. For example, the carry case 200 can include an externally accessible USB or other type of charge port that can include a waterproof or water resistant access pan (not illustrated). In this manner, a user need not open the carry case 200 to access a charge port, or communication port, of the carry case 200. Additionally, enabling access to converted solar energy can allow a user to charge electronic devices in remote places. This can be an advantage for the outdoorsman, mobile professional, military personnel, and developing third world countries that lack the infrastructure to access terrestrial electrical power.

According to a further aspect, the carry case 200 can be configured in various shapes and sizes. For example, the carry case 200 can be reduced in size to accommodate a single electronic device. As such, the carry case 200 can include solar panel array coupled to an exterior portion of the carry case 200 and can further include a cooling device, such as a micro-fan, thermo-cooling device, or other device that can reduce an operating temperature. As such, the carry case 200 is not restricted in size, or the types of cooling devices that can be combined with, or used in place of, a fan.

FIG. 3 illustrates a solar energy charge and cooling system for a carry case according to one aspect of the disclosure. The solar energy charge and cooling system (SECCS), illustrated generally at 300, can include a solar panel array 302 coupled to an energy repository 304 such as one or more auxiliary batteries operable to store direct current (DC) power. The SECCS 300 can also include a first USB port 306, a second USB port 308, and a third USB port 310 coupled to the solar panel array 302 and the energy repository 304. The SECCS 300 can also include a device port 340 that can be configured to be coupled to a specific electronic device and in one form can be configured to be coupled to a portable computing system (not illustrated). The SECCS can also include a docking station 312 configured to enable a portable system or laptop computer to be coupled to the docking station to enable access to one or more resources of the SECCS 300.

The device port 340 can include a separate power circuit than the USB port 306 to couple converted solar energy to an electronic device coupled to the device port 312. The SECCS 300 further includes an AC adapter input 318 operable to be coupled to a regulator 314 of the SECCS 300. The AC adapter input 318 can coupled an external AC power source to the regulator 314 to enable use of an external AC power source. The AC adapter input 318 can be configured to be used with a specific type of AC adapter, however in other forms, various adapter plugs can be used to reconfigure the AC input adapter 318 to be used with various types of input AC power sources as needed or desired.

The power regulator 314 can further be coupled to the charge converter 316 operable to couple power directly to the device port 340. In other forms, the regulator 314 can also be coupled to one or more of the USB ports 306, 308, 310 via a USB bus coupled to the regulator 314 to regulator power output to the USB ports 306, 308, 310. The power regulator 314 can also be coupled to the charge converter and the energy repository.

The SECCS 300 further includes a fan controller 320 that can be powered using the energy repository 304. The fan controller 320 can be used to control a first fan 322, a second fan 324, a third fan 326, a fourth fan 328 or additional fans as needed or desired. In one embodiment, the first fan 322 and the second fan 324 can be coupled to a lid of a notebook computer system carry case such as the carry case 100 illustrated in FIG. 1 or the carry case 200 illustrated in FIG. 2. In another form, the third fan 326 and the fourth fan 328 can be coupled to a lower portion of a notebook carry case to cool a lower portion of a notebook computer system that can be mounted within a carry case.

The fan controller 320 of the SECCS 300 can also be coupled to one or more temperature sensors 332 operable to couple a voltage or temperature input to the fan controller to initiate activating one or more of the fans 322, 324, 326, 328. The temperature sensors 332 can include one or a combination of temperature sensors operable to detect various temperatures between 30 and 75 degrees Celsius, or other ranges as applications warrant, and operable to initiate activation of one or more fans 322, 324, 326, 328 to cool various portions of a carry case. For example, in one embodiment, if a carry case is in a closed position and a temperature exceeds a threshold, one or more of the temperature sensors 332 can couple the temperature input to the fan controller 320 and the fan controller can activate one or more of the fans 322, 324, 326, 328 to cool contents housed within the carry case.

According to a further aspect, the fan controller 320 can also be coupled to a fan control switch input logic 330 that can be used to detect one or more operating conditions. In one form, the fan control switch logic 330 can be incorporated as a part of the fan controller 320 or other device of the SECCS 300 as needed or desired. A manual fan switch can also be used to manually activate or deactivate one or more of the fans as desired. In one embodiment, the fan control switch logic 330 can include a manual input 334 operable to manually enable use or activation of one or a combination of fans 322, 324, 326, 328. The fan control logic 336 can also include an automatic input 336 operable to enable automatic activation of the one or a combination of the fans 322, 324, 326, 328. A lid open and closed input 338 can couple a signal to the fan control switch logic 330 to indicate whether a lid to a carry case may be opened or closed and activate or deactivate one or a combination of fans 322, 324, 326, 328 in response to the activation. As such, the fan controller 320 can receive inputs from the fan control switch logic 330 and the temperature sensors 332 to determine whether one or a combination of fans 322, 324, 326, 328 should be activated or deactivated. For example, if the temperatures sensors 332 detect a relative high temperature, and the fan control switch logic 330 detects a lid of a carry case being open, fans coupled to a lid portion may be deactivated (e.g. energy would be conserved given the fans would not be aligned with contents of a carry case). Additionally, the fan control 320 can maintain or initiate use of fans coupled to a bottom portion of a carry case to ensure the contents of a bottom portion of carry case are maintained. In one form, each fan can include a separate fan controller 320, fan switch control logic 330, or any combination thereof.

According to one aspect, the solar panel array 302 can be used to trickle charge an energy repository 304, such as an auxiliary battery. The solar panel array 302 can further supply additional power to a laptop, cell phones, iPods, or other electronics coupled to one or more ports of the SECCS 300. During use, the solar panel, notebook computer, auxiliary battery, other electronic devices, or various combinations thereof, can produce heat when in use or being charged. The temperature sensors 332 can sense a specific temperature value and couple an input to the fan controller 320. The fan controller 320 can enable one or more of the fans 322, 324, 326, 328 to cool the notebook, the solar panel array 302, or various other electronic devices. Additionally, through cooling the notebook and solar panel array 302, efficient conversion of solar energy can be realized. Further, efficient processing of the notebook computer can also be realized.

According to another aspect, as the temperature sensors 332 sense a reduction in temperature, one or more of the fans associated with a specific region can be slowed or turned off based on a localized temperature sensed. In this manner, if a region of the carry case reaches an acceptable temperature, a fan can be turned off to conserve use of energy. Additionally, if one or more temperatures sensed by temperature sensors 332 exceed an acceptable limit, one or more fans 322, 324, 326, 328 can be operated as needed or desired.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A portable storage apparatus comprising:
a solar panel array coupled to an exterior portion of a lid of a housing, the solar panel array operable to convert solar energy to direct current (DC) power; and
a first fan coupled to an interior portion of the housing operable to reduce an operating temperature within the housing.

2. The portable storage apparatus of claim 1 comprising:
a first temperature sensing device configured to sense an internal temperature of a cavity formed from the housing, the housing including a bottom portion;
a second fan coupled to the interior portion of the housing and responsive to the first temperature;
wherein the second fan is located proximal to the bottom portion configured to mount a portable computer system, the second fan configured to reduce an operating temperature of the portable computer system; and
wherein the first fan is located proximal to the lid portion and configured to reduce an operating temperature of the solar panel array.

3. The portable storage apparatus of claim 1 further comprising a device specific charge port coupled to a charge circuit operable to couple the converted solar energy to the device specific charge port to charge an electronic device.

4. The portable storage apparatus of claim 1 further comprising a universal serial bus (USB) port coupled to a charge circuit operable to couple the converted solar energy to a USB device coupled to the USB port.

5. The portable storage apparatus of claim 1 further comprising:
a first universal serial bus (USB) port coupled to the interior portion of the housing, the first USB port operable to be coupled to a USB resource, wherein the first USB port is configured to charge the USB resource using the converted solar energy; and
a second USB port communicatively coupled to the first USB port and operable to enable a portable computer system access to the USB resource.

6. The portable storage apparatus of claim 1 further comprising:
a docking station coupled to the interior portion of the housing and configured to interface with a portable computer system;
an interface of the docking station operable to enable the portable computer system access to a resource external to the portable computer system;
wherein the resource includes a power circuit operable to charge a battery of the portable computer system; and
wherein the resource includes a USB communication bus operable to couple a USB resource to the portable computer system.

7. The portable storage apparatus of claim 6 further comprising:
a second fan operable to reduce an operating temperature of the portable computer system when docked to the docking station; and
wherein the power circuit includes:
a first battery operable to store the converted solar energy operable to charge a second battery of the portable computer system; and
an AC charge port operable to couple an AC power source to an AC to DC charge converter, wherein the AC charge port is further configured to couple converted AC power to the first battery to charge the first battery.

8. The portable storage apparatus of claim 1 further comprising:
a first power circuit configured to output power to a non-USB enabled device coupled to a device port; and
a second power circuit configured to output power to a USB enabled device coupled to a USB port.

9. The portable storage apparatus of claim 1 further comprising:
a first temperature sensor operable to initiate activation of the first fan and a second fan to alter an operating temperature of the solar panel array; and
a second temperature sensor operable to initiate activation of a third fan and a fourth fan to alter an operating temperature of an electronic device stored within the housing.

10. The portable storage apparatus of claim 1 further comprising:
a manual control input source operable to couple a manual control input signal to a fan control operable to enable and disable use of the first fan;
a lid status input source operable to couple an lid status input to the fan control; and
wherein the fan control is configured to be responsive to the manual control input signal and the lid status input signal to activate and deactivate the first fan.

11. A solar energy charge and cooling system of a carry case, the system comprising:
a first fan operable to be coupled to an interior lid portion of a housing configured to store a portable electronic device;
a solar panel array operable to be coupled to an exterior portion of the housing and operable to convert solar energy to power the first fan; and
wherein the first fan is responsive to the converted solar energy to reduce an operating temperature within the housing.

12. The solar energy charge and cooling system of claim 11 wherein the first fan is located proximal to the solar panel array, the first fan configured to reduce an operating temperature of the solar panel array.

13. The solar energy charge and cooling system of claim 11 further comprising:
a second fan coupled to a lower portion of the housing and operable to cool electronics stored within the housing; and
an energy storage device configured to store converted solar energy as stored energy, the energy storage device further configured to output the stored energy to the first fan and the second fan to cool the electronics and the solar panel array.

14. The solar energy charge and cooling system of claim 11 further comprising an AC adapter port coupled to an energy storage device, wherein the AC adapter port is configured to couple converted AC power to the energy storage device.

15. The solar energy charge and cooling system of claim 11 further comprising a fan controller responsive to a first temperature sensing device operable to initiate activation of the a first fan.

16. The solar energy charge and cooling system of claim 11 further comprising:
wherein the first temperature sensor is operable to initiate activation of the first fan and a second fan to reduce an operating temperature of the solar panel array; and
a second temperature sensor operable to initiate activation of a third fan and a fourth fan to reduce an operating temperature of a portable electronic device stored within the housing.

17. The solar energy charge and cooling system of claim 16 further comprising:
a manual control input source operable to enable and disable use of the first fan;
a lid status input source operable to couple an input to a fan control logic coupled to the first fan;
wherein the fan control logic is responsive to the manual control input source and the lid status input source to activate and deactivate the first fan; and
wherein the third fan is not responsive to the fan control logic.

18. A carry case comprising:
a solar panel array coupled to an exterior portion of a lid of a housing, the solar panel array operable to convert solar energy to direct current (DC) power;
a first temperature sensing device configured to sense an internal temperature of a cavity formed within the housing, wherein the housing includes the lid and a bottom portion;
a fan controller responsive to the first temperature sensing device and operable to enable activation of the a first fan coupled a first fan coupled to an interior lid portion of a housing;
a second fan coupled to the bottom portion of the housing;
wherein the first fan is proximally located to the solar panel array to reduce an operating temperature of the solar panel array using energy converted by the solar panel array; and
wherein the second fan is proximally located to a portable computer storage area of the bottom portion of the housing, the second fan responsive to the converted solar energy to reduce an operating temperature of the portable computer.

19. The notebook carry case of claim 18 further comprising:
a first universal serial bus (USB) port coupled to an interior housing and operable to couple converted solar power to a USB enabled device coupled to the first USB port; and
wherein the first USB port is further configured to enable access to the USB enabled device by a portable computer system when coupled to the first USB port using a second USB port.

20. The notebook carry case of claim 19 further comprising:
a docking station coupled to the interior housing and configured to interface with a portable computer system stored within the interior housing;
an interface of the docking station operable to enable a portable computer coupled to the docking station access to a resource; and
wherein the resource includes a USB bus operable to enable access to a USB hub configured to couple a USB resource to the portable computer.
